(19) United States
(12) Patent Application Publication
(10) Pub. No.: US 2019/0382889 A1
(43) Pub. Date: Dec. 19, 2019

(54) TECHNIQUE TO ENABLE HIGH TEMPERATURE CLEAN FOR RAPID PROCESSING OF WAFERS

(71) Applicant: Applied Materials, Inc., Santa Clara, CA (US)

(72) Inventors: Venkata Sharat Chandra PARIMI, Sunnyvale, CA (US); Zhijun JIANG, Sunnyvale, CA (US); Ganesh BALASUBRAMANIAN, Fremont, CA (US); Vivek Bharat SHAH, Sunnyvale, CA (US); Shailendra SRIVASTAVA, Fremont, CA (US); Amit Kumar BANSAL, Milpitas, CA (US); Xinhai HAN, Santa Clara, CA (US); Vinay K. PRABHAKAR, Cupertino, CA (US)

(21) Appl. No.: 16/422,793

(22) Filed: May 24, 2019

Related U.S. Application Data
(60) Provisional application No. 62/685,789, filed on Jun. 15, 2018.

(51) Int. Cl. C23C 16/44; H01J 37/32

(52) U.S. Cl. CPC C23C 16/4405; H01J 37/32862

(57) ABSTRACT

Implementations of the present disclosure generally provide improved methods for cleaning a vacuum chamber to remove adsorbed contaminants therefrom prior to a chamber seasoning process while maintaining the chamber at desired deposition processing temperatures. The contaminants may be formed from the reaction of cleaning gases with the chamber components and the walls of the vacuum chamber.

### CROSS-REFERENCE TO RELATED APPLICATIONS

This application claims benefit of U.S. provisional patent application Ser. No. 62/685,789, filed Jun. 15, 2018, which is herein incorporated by reference

### BACKGROUND

### Field

Embodiments of the present disclosure generally relate to improved methods of controlling a processing chamber during normal use and/or during fault conditions to reduce contamination of substrates processed therein.

### Background

Plasma processing reactors used in the semiconductor industry are often made of aluminum-containing materials for processing performance and/or cost reasons. After processing a number substrates, or wafers, in the processing region of a processing chamber it is commonly required that the processing region needs to be cleaned by use of an in-situ cleaning process. Typically, during an in-situ cleaning process that uses a fluorinated cleaning gas to clean the processing environment, aluminum fluoride is generated on the surface of the exposed aluminum-containing parts. The aluminum fluoride layer formation during the regularly performed in-situ cleaning processes continually etches the surface of the aluminum-containing parts. Referring to FIG. 1A, during an in-situ cleaning process within a plasma processing chamber, a cleaning gas NF₃ is distributed towards the substrate support 102 from the gas inlet manifold 104. Typically, the substrate support 102 is formed from an aluminum containing material, such as an aluminum nitride (AlN) material, and the chamber walls 103 may be formed from an aluminum containing material or a stainless steel material. Particularly in a plasma enhanced chemical vapor deposition chamber, a layer of aluminum fluoride 106 forms on the exposed aluminum surfaces, for example the surfaces of the substrate support 102 when fluorine containing gases such as NF₃ or CF₄ are used as the in-situ chamber cleaning gas. Referring to FIG. 1B, once the cleaning process is complete and the NF₃ containing plasma is extinguished, it has been observed that when the substrate support 102 is heated to a temperature greater than 480 degrees Celsius the surfaces of the substrate support will become etched as the previously formed layer of aluminum fluoride 106 sublimates therefrom. Also, as the aluminum fluoride sublimates, the aluminum fluoride is transported to the adjacent chamber components, such as the gas inlet manifold 104 and walls 103 of the process chamber. The aluminum fluoride deposits on the gas inlet manifold 104 and forms a deposited aluminum fluoride layer 110. Referring to FIG. 1C, the deposited aluminum fluoride layer 110 on the gas inlet manifold 104 may flake off during a subsequent substrate process in the chamber causing the generated particles 113 to contaminate the surface 112 of the substrate 115. Aluminum fluoride is difficult to remove from chamber components by conventional in-situ cleaning processes, and thus after the chamber components, such as the gas inlet manifold 104 has become contaminated the process chamber must be cooled down, opened to the atmospheric environment and manually cleaned by a technician. As a result, the deposition of aluminum fluoride on the process chamber components causes significant particle problems, significant processing tool down time and process drift.

As deposition process temperature requirements continue to rise to temperatures above 600 degrees Celsius, the sublimation of the formed aluminum fluoride layer becomes even more severe. Therefore, there is a need in the art to provide an improved process to minimize the creation of the aluminum fluoride layer and deposition of the sublimated aluminum fluoride material on exposed processing chamber components. There is also a need for an improved process to clean and prepare the processing region of a process chamber for sequentially processing multiple substrates at high temperatures without the need to frequently take the processing chamber down to remove the unwanted contamination described above.

### SUMMARY

Implementations of the present disclosure provide methods for treating a processing chamber. In one implementation, the method includes performing a first process within a processing region of the substrate processing chamber, wherein a substrate support disposed within the processing region is maintained at a first process temperature that is above 600 degrees Celsius. The method further includes performing an in-situ chamber clean process within the substrate processing chamber, wherein the in-situ chamber clean process comprises maintaining the substrate support temperature at a clean process temperature that is above 600 degrees Celsius, controlling the processing region to a pressure above 8 Torr, and performing a chamber clean process using a cleaning gas, wherein the cleaning gas reacts with a residue disposed on a surface of a chamber component disposed within the substrate processing chamber to remove the residue therefrom. The substrate processing chamber is purged while maintaining the substrate support at a purge process temperature that is above 600 degrees Celsius.

In another implementation, the method includes controlling a substrate processing chamber comprising maintaining a substrate support disposed within a processing region of a substrate processing chamber at a first process temperature that is above 600 degrees Celsius. A process parameter of the substrate processing chamber is monitored and the process parameter is compared with a value stored in a memory of the substrate processing chamber to determine a chamber fault is likely to occur in the future based on the comparison of the process parameter with the value stored in memory. The pressure is adjusted within the substrate processing chamber to a pressure above 8 Torr after determining that the chamber fault is likely to occur and after determining that the substrate support is maintained at a temperature that is above 600 degrees.

In yet another implementation, the method of treating a substrate processing chamber comprises performing a first process within the substrate processing chamber with a substrate support maintained at a temperature above 600 degrees Celsius. The method further includes monitoring a process parameter of the substrate processing chamber and comparing the process parameter with a value stored in a memory of the substrate processing chamber, then adjusting a pressure within the substrate processing chamber to a pressure above 8 Torr when a chamber fault is detected, wherein the chamber fault is detected by comparing the process parameter with the value stored in memory.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. It is to be noted, however, that the appended drawings illustrate only typical embodiments of this disclosure and are therefore not to be considered limiting of its scope, for the disclosure may admit to other equally effective embodiments.

FIG. 1A depicts a side view schematic of chamber components undergoing an NF3 clean process

FIG. 1B depicts a side view schematic of aluminum fluorine sublimation from a chamber component.

FIG. 1C depicts a side view schematic of aluminum fluorine flaking during a chamber process.

FIG. 2 is a schematic top view diagram of an illustrative multi-chamber processing system 200 that can be adapted to perform a chamber clean and season method as disclosed herein.

FIG. 3. is a chart that illustrates a comparison of aluminum fluoride sublimation rates as a function of chamber pressure, according to one or more embodiments disclosed herein.

FIG. 4A is a flow chart of that illustrates an in-situ clean process and chamber seasoning process, as per one embodiment as disclosed herein.

FIG. 4B includes a chart that illustrates an example of the variation of chamber pressure as a function of time according to the method depicted in FIG. 4A.

FIG. 4C depicts a side schematic view of chamber components undergoing a chamber clean process, according to one embodiment as disclosed herein.

FIG. 4D depicts a side schematic view of chamber components undergoing a chamber seasoning process, according to one embodiment as disclosed herein.

FIG. 5 depicts a flow chart of a method for protecting the chamber components from aluminum fluoride sublimation upon the detection of a chamber fault, as per one embodiment as disclosed herein.

FIG. 6 depicts a flow chart of a method for protecting the chamber components from aluminum fluoride sublimation upon the anticipated detection of a chamber fault, as per one embodiment as disclosed herein.

FIG. 7 depicts a chart of chamber pressure and time according to the method depicted in FIG. 6.

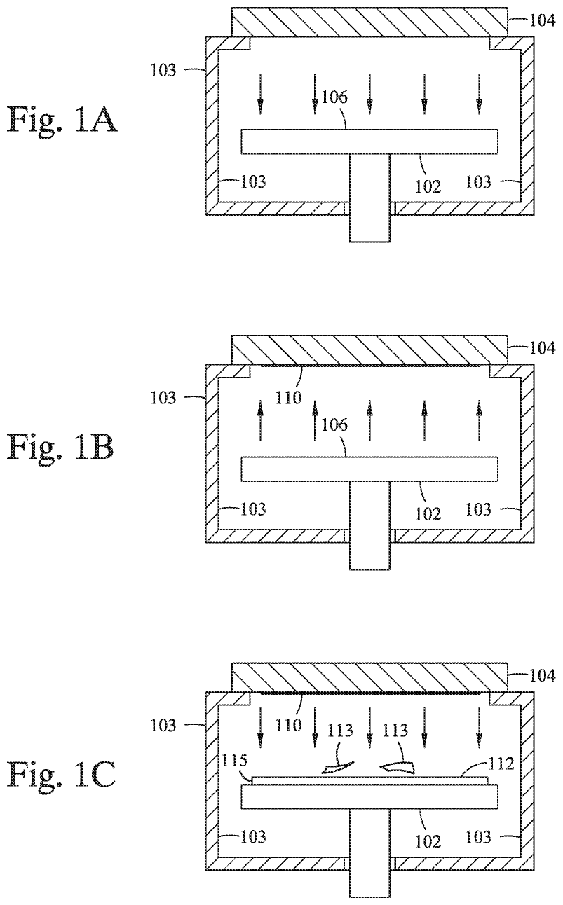

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Implementations of the present disclosure generally provide improved methods for cleaning a vacuum chamber to remove adsorbed contaminants therefrom prior to a chamber seasoning process while maintaining the chamber at desired deposition processing temperatures. The contaminants may be formed from the reaction of cleaning gases with the chamber components and the walls of the vacuum chamber. For example, and as discussed above, it has been found that during and after performing an in-situ cleaning process in a vacuum chamber that includes bringing a fluorinated cleaning gas in contact with aluminum containing chamber components, which are heated to a high temperature (e.g., >480° C.), an aluminum fluoride layer will be formed thereon. Due to the high temperature and partial pressure of the aluminum fluoride material, the formed aluminum fluoride layer will sublimate within the vacuum chamber during processing which will undesirably cause etching of the heated aluminum containing components on which the layer was formed and generate contamination that will affect the process performance of the vacuum chamber. Therefore, there is a need for an improved process of cleaning and preparing a process chamber so that it can desirably sequentially process multiple substrates at high processing temperatures.

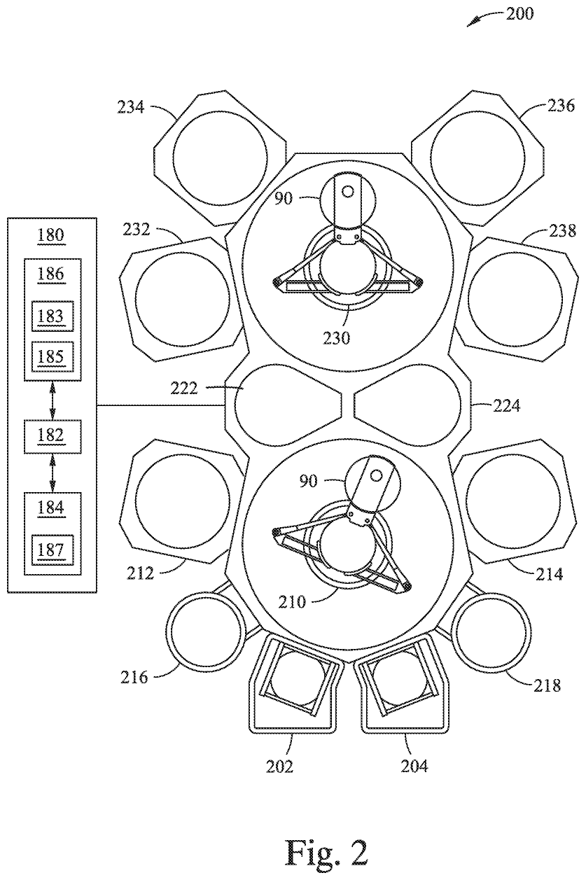

FIG. 2 is a schematic top view diagram of an illustrative multi-chamber processing system 200 that can be adapted to perform chamber cleaning processes and seasoning processes as disclosed herein within a processing chamber of the chamber processing system 200. The system 200 can include one or more load lock chambers 202 and 204 for transferring substrates 90 into and out of the system 200. Generally, the system 200 is maintained under vacuum and the load lock chambers 202 and 204 can be “pumped down” to introduce substrates 90 introduced into the system 200. A first robot 210 can transfer the substrates 90 between the load lock chambers 202 and 204, and a first set of one or more substrate processing chambers 212, 214, 216, and 218. Each processing chamber 212, 214, 216, and 218 is configured to be at least one of a substrate deposition process, such as cyclical layer deposition (CLD), atomic layer deposition (ALD), chemical vapor deposition (CVD), physical vapor deposition (PVD), etch, degas, pre-cleaning orientation, anneal, and other substrate processes.

The first robot 210 can also transfer substrates 90 to or from one or more transfer chambers 222 and 224. The transfer chambers 222 and 224 can be used to maintain ultrahigh vacuum conditions while allowing substrates 90 to be transferred within the system 200. A second robot 230 can transfer the substrates 90 between the transfer chambers 222 and 224 and a second set of one or more processing chambers 232, 234, 236 and 238. Similar to the processing chambers 212, 214, 216, and 218, the processing chambers 232, 234, 236, and 238 can be outfitted to perform a variety of substrate processing operations including cyclical layer deposition (CLD), atomic layer deposition (ALD), chemical vapor deposition (CVD), physical vapor deposition (PVD), etch, pre-clean, degas, and orientation, for example.

In FIG. 2, a controller 180 may be coupled to the multi-chamber processing system 200 to control the system functions and processing conditions within the processing chambers. The controller 180 comprises a processor 182, support circuitry 184, and memory 186 containing associated software applications 183 and stored data 185. The controller 180 may be one of any form of a general purpose computer processor that can be used in an industrial setting for controlling various chambers and sub-processors. Processor 182 may be a hardware unit or combination of hardware units capable of executing software applications and processing data. In some configurations, the processor 182 includes a central processing unit (CPU), a digital signal processor (DSP), an application-specific integrated circuit (ASIC), and/or combination of such units. Processor 182 is configured to execute the one or more software applications 183 and process the stored data 185, which are include in memory 186. The controller 180 may be coupled to another controller that is located adjacent individual chamber components. Bi-directional communications between the controller 180 and various other components of the multi-chamber processing system 200 are handled through numerous signal cables collectively referred to as signal buses (not shown).

The support circuitry 184 is couple to memory 186 and processor 182, and may include I/O devices 187. I/O devices 187 may include devices capable of receiving input and/or devices capable of providing output. For example, I/O devices 187 may include one or more sensors that may include temperature sensors, pressure sensors, flow rate sensors, or any other sensors that monitor physical conditions of a process or physical properties of a work piece within the processing chambers. The I/O devices 187 may include one or more timing devices such as a clock, that are configured to provide time related information to the processor 182. Other I/O devices 187 may include a display, such a touch screen display, audio outputs and a keyboard.

Memory 186 may be any technically feasible type of hardware unit configured to store data. For example, memory 186 may be a hard disk drive, a random access memory (RAM) module, a flash memory unit, or a combination of different hardware units configured to store data. Software applications 183, which are stored within the memory 186, include program code that may be executed by processor 182 in order to perform various functionalities associated with the multi-chamber processing system 200.

The stored data 185 may include any type of information that relates to desired control parameters, system configuration data, chamber performance and faults data, process data, equipment constants, historical data and other useful information. The stored data 185 may include information that is delivered to and/or received from the multi-chamber processing components, for example chambers 212, 214, 216, 218, 232, 234, 236 and 238. The software applications 183 may generate control signals based on the stored data 185. The stored data 185 may reflect various data files, settings and/or parameters associated with the multi-chamber processing system 200 and/or desired function of the multi-chamber processing system 200.

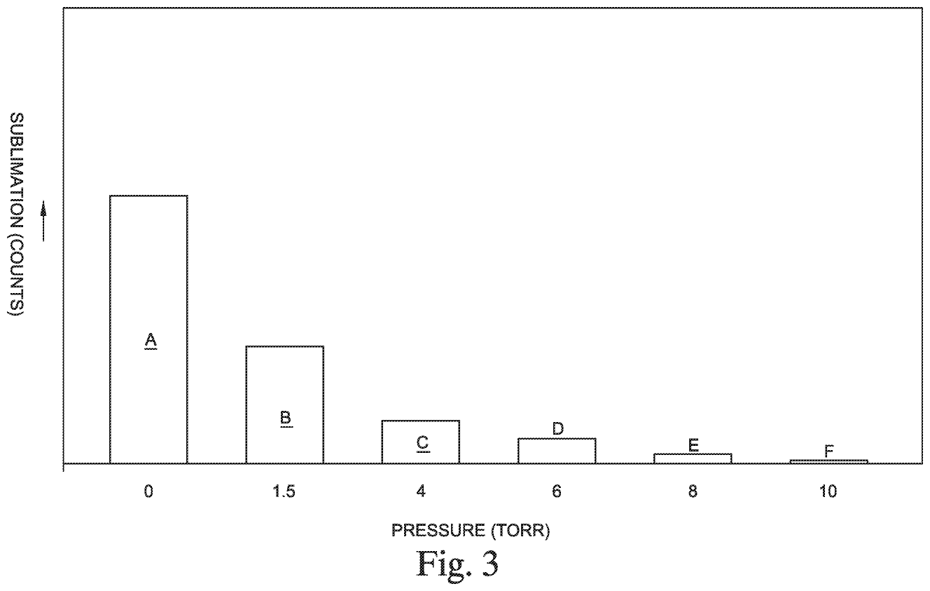

As discussed above, it has been found that during and after performing an in-situ cleaning process in a vacuum processing chamber, while an aluminum containing chamber component (e.g., substrate support) is maintained at a high temperature (e.g., >480° C.), the sublimation of a formed aluminum fluoride layer therefrom can reduce the lifetime of the chamber components and contaminate the vacuum chamber and wafers processed in the vacuum processing chamber. The detrimental effects created by the sublimation of the formed aluminum fluoride material from the heated chamber component(s) exponentially increases as the component's temperature is increased to a temperature above 600° C. By use of the apparatus and one or more methods disclosed herein, sublimation of a formed aluminum fluoride material can be kept to a low sublimation rate, such as a rate equal to the sublimation rate of the aluminum fluoride layer at a temperature below 480° C. In some embodiments the sublimation of the formed aluminum fluoride material can be controlled by maintaining the chamber pressure at pressures greater than about 5 Torr, such as for example a pressure of greater than about 8 Torr, such as greater than about 10 Torr. In another example, the chamber pressure is maintained at a pressure between about 5 Torr and about 760 Torr, such as a pressure between about 8 Torr and about 500 Torr, or even a pressure between about 10 Torr and about 100 Torr. As an example, FIG. 3 depicts a chart showing the sublimation rates of aluminum fluoride from a component that is maintained at a temperature above 600° C. as compared to chamber pressures ranging from less than 0.1 Torr to 10 Torr. In FIG. 3, the rate of aluminum fluoride sublimation is displayed in counts per second on the y-axis and the chamber pressure in Torr is shown on the x-axis. As shown in FIG. 3, the sublimation rate of aluminum fluoride at 0.1 Torr, depicted as bar A, is approximately double the amount of the sublimation rate of the aluminum fluoride layer at 1.5 Torr as depicted in bar B and is greater than 50 times the sublimation rate of the aluminum fluoride layer at pressures greater than 8 Torr. The rates of aluminum fluoride sublimation continue to decrease as shown by bars C, D and E as the pressure in the processing chamber is increased to from 4 Torr, to 6 Torr and 8 Torr. Chamber pressures of greater than 8 Torr, such as 10 Torr and greater have been found to achieve a negligible or substantially undetectable material sublimation rate at high component part processing temperatures, such as an aluminum containing component that is maintained at a temperature equal to or greater than 600 degrees Celsius. By performing high temperature cleaning processes at high chamber pressures, such as about 10 Torr, the amount of aluminum fluoride sublimation can be effectively reduced resulting in fewer manual cleanings of the process chamber and its components, reduced substrate contamination during processing and an improved chamber component lifetime. In one example of a clean process, the chamber pressure is maintained at a pressure of greater than about 8 Torr. In one example, the clean process pressure is maintained at a pressure between about 8 Torr and about 760 Torr, such as a pressure between about 10 Torr and about 500 Torr, or even a pressure between about 15 Torr and about 100 Torr.

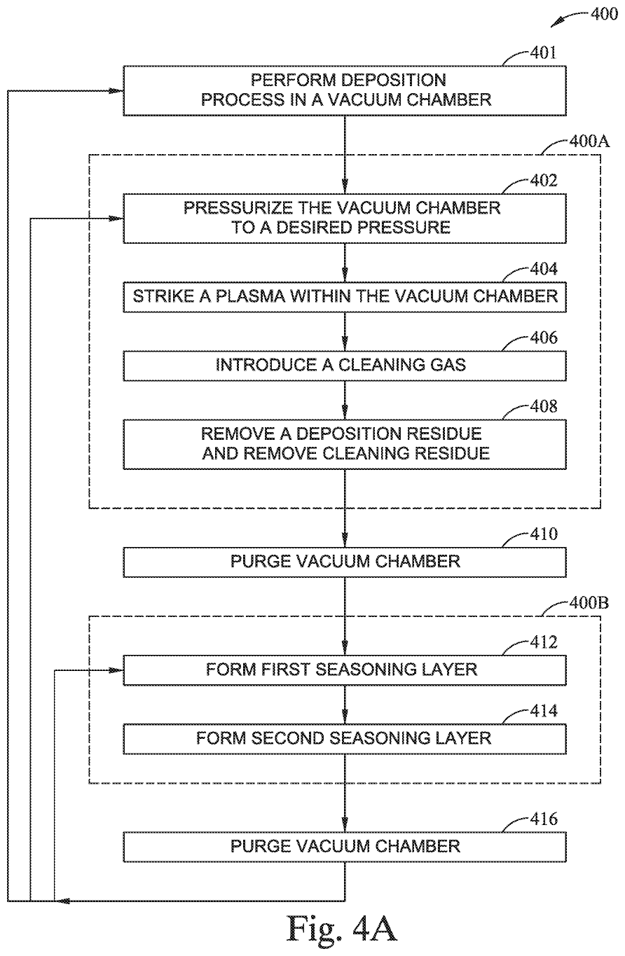

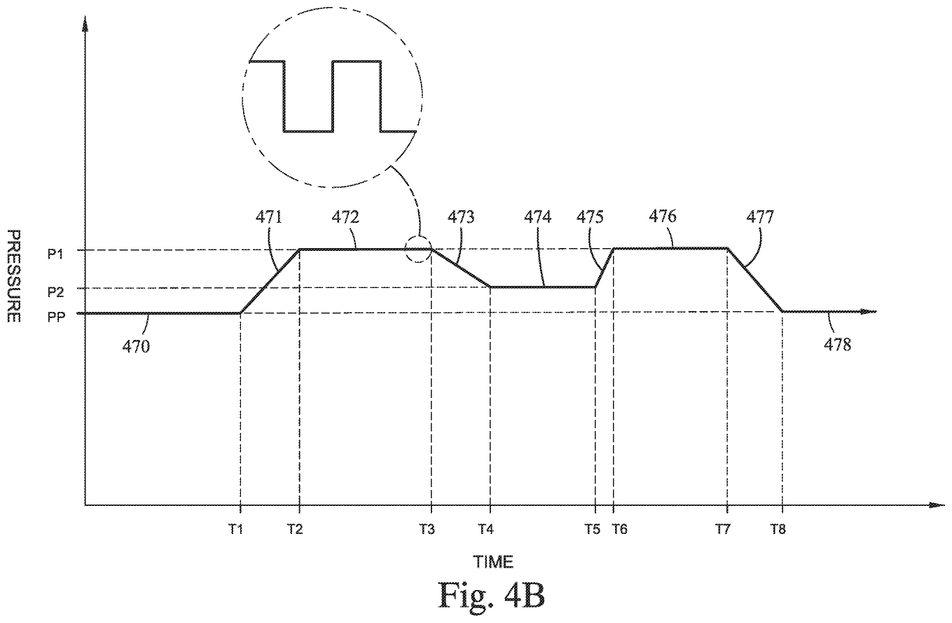

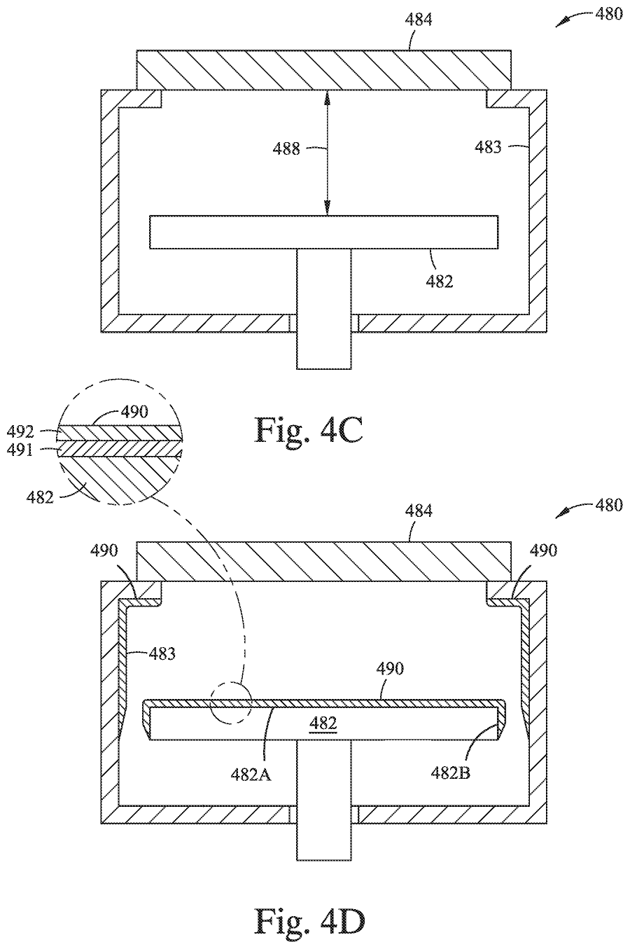

FIG. 4A depicts a flow chart of a method 400 for in-situ cleaning a vacuum chamber and preparing the vacuum chamber for the next substrate deposition process according to implementations of the present disclosure. The vacuum chamber may be any suitable substrate processing chamber using thermal and/or plasma to enhance the performance of the process, for example a chemical vapor deposition (CVD) chamber or a plasma-enhanced chemical vapor deposition (PECVD) chamber. In one example, the vacuum chamber is an RF powered plasma processing chamber having at least a gas inlet manifold, a substrate support, and a vacuum pump system.

FIG. 4A shows cleaning method 400A which provides for a cleaning plasma that cleans deposition process residue and cleaning process residue from the vacuum chamber. FIG. 4 also illustrates seasoning operations 400B which provides for seasoning or coating of one or more of the interior chamber components, such as the substrate support, with a seasoning layer (e.g., silicon oxide layer) to prepare and protect the interior components for the subsequent substrate deposition steps. FIG. 4B depicts a chart showing the chamber pressure against time according to operations depicted in FIG. 4A.

Referring to both FIGS. 4A and 4B, the method 400 may be performed before and/or after processing of a single substrate or batch of substrates within the vacuum chamber. Block 401 of FIG. 4A, and line 470 of FIG. 4B, represents the processing of a substrate or batch of substrates (e.g., substrates) within the processing chamber where the substrate is processed for a determined period of time and at a determined processing pressure PP. Such processes may include, for example, depositing a material layer on a surface of one or more substrates. In one example, the material layer deposition process is performed with the substrate support temperature at a high temperature, such as a temperature greater than 600 degrees Celsius, for example a temperature of 650 degrees Celsius. Although various operations are illustrated in the drawings and described herein, no limitation regarding the order of such operations or the presence or absence of intervening operations is implied. Operations depicted or described as sequential are, unless explicitly specified, merely done so for purposes of explanation without precluding the possibility that the respective operations are actually performed in concurrent or overlapping manner, at least partially if not entirely.

In one implementation, referring to FIGS. 4A and 4B, once a substrate has completed block 401, such as a high temperature processing step at a pressure PP, the substrate is transferred out of the plasma processing chamber at time T1. The cleaning method 400A of method 400 is then used to clean and prepare the processing region of the processing chamber for one or more additional substrates to be subsequently processed therein. The preparation process(es) performed in cleaning method 400A improves chamber performance resulting in increased deposition uniformity from wafer to wafer and decreases the number of manual chamber cleans.

The cleaning method 400A starts at block 402 by pressurizing the plasma processing chamber as depicted as line 471 in FIG. 4B. For example, the 300 mm plasma processing chamber is pressurized to a target pressure P1, where P1 is greater than about 8 Torr and less than atmospheric pressure, such as about 10 Torr, to minimize aluminum fluoride sublimation as compared to chamber pressure at lower temperatures, as discussed above in reference to FIG. 3. The process of controlling the pressure in the processing region begins at time T1 and ends at time T2, and may be between about 1 second to about 12 seconds depending on chamber size, for example about 8 seconds. The time it takes to adjust the pressure in the processing region of the processing chamber to a pressure P1 may vary depending on the size of the plasma processing chamber, the pumping speed of the pump used to maintain the pressure in the processing region, the flow rate setting for a gas (e.g., cleaning gas or inert gas) used to adjust the chamber pressure and/or the conductance of the residual gases flowing through the processing region to the pump. At block 402, the plasma processing chamber is filled with a plasma initiation gas, such as argon, nitrogen, or helium etc., pressuring the processing chamber to target pressure P1. The substrate support temperature may be maintained at 600 C or higher, such as 650 C. In one implementation, the substrate support may be maintained at the temperature at which the previous deposition process was performed, such as for example 650 degrees Celsius. In one implementation the substrate support temperature is maintained at 650 degrees Celsius for the duration of method 400. The benefit of maintaining the substrate support at a fixed temperature for the duration of the method 400 is that it will greatly decrease the clean/material deposition cycle time because the substrate support temperature does not need to be ramped down and then ramped back up for each substrate process and clean process cycle (e.g., process operation blocks 401-416) performed in the vacuum process chamber. For example, if the substrate support temperature is decreased to 550 degrees Celsius during one or more of the process steps to decrease the aluminum fluoride sublimation rate, the temperature ramp time can often be as long as between 15 minutes to 30 minutes to decrease the substrate support temperature from the processing temperature to a cleaning process temperature (e.g., 650° C. dropped to 550° C.) or increase the substrate support temperature from 550 degrees Celsius back to a target material deposition substrate support temperature of, for example 650 degrees Celsius.

Blocks 404, 406 and 408 associated with cleaning method 400A correspond with line 472, between times T2 and T3, as shown in FIG. 4B. At block 404 of FIG. 4A and time T2 of FIG. 4B, the substrate support temperature is maintained at a high temperature greater than 600 degrees Celsius, such as target substrate support temperature 650 degrees Celsius, and the plasma processing chamber is maintained at the target processing pressure P1, such as for example, about 10 Torr or greater. In one example, the plasma initiation gas is argon. The plasma initiation gas may be flowed into the plasma processing chamber for about 1 second to about 20 seconds, for example about 10 seconds for a 300 mm plasma processing chamber, until gas flow is stabilized. A plasma power of between about 0.56 watts/cm2 and 6 watts/cm2 may be supplied to the plasma processing chamber to ignite the plasma.

At block 406 of FIG. 4A, and line 472 of FIG. 4B, while maintaining the chamber pressure at target pressure P1, such as 10 Torr to prohibit aluminum fluoride sublimation, a cleaning gas is introduced into the plasma processing chamber through the gas inlet manifold. The cleaning gas may include a fluorine containing gas (e.g., F2, atomic fluorine (F) and/or fluorine radicals (F*)). The cleaning gas may comprise a perfluorinated or hydrofluorocarbon compound, for example NF3, CF4, C2F6, CHF3, C3F8, C4F8, and SF6. In one exemplary implementation, the cleaning gas is NF3. For a 300 mm plasma processing chamber, the cleaning gas may be introduced into the plasma processing chamber at a flow rate of about 150 sccm to about 800 sccm, for example about 300 sccm to about 600 sccm for about 1 second to about 6 seconds, or for example about 3 seconds. It is contemplated that the cleaning gas may be introduced into the plasma processing chamber from a remote plasma system.

At block 408 of FIG. 4A, line 472 of FIG. 4B, and referring to FIG. 4C, the electrode spacing, distance 488 between the gas inlet manifold electrode 484 and a substrate support electrode 482 of the plasma processing chamber 480 is adjusted to control or enhance the effectiveness of the chamber cleaning process. While maintaining chamber pressure at the target processing pressure P1 (e.g., 10 Torr), maintaining the substrate support temperature at temperature above 600 degrees Celsius, for example 650 degrees Celsius, and flowing the cleaning gas into the plasma processing chamber, the electrode spacing, distance 488 between a gas inlet manifold electrode 484 and a substrate support electrode 482 of the plasma processing chamber 480 is adjusted to control or enhance the effectiveness of the chamber cleaning process. For example, in one implementation, the cleaning process includes a two-stage process. A first stage includes forming a first relatively large electrode spacing between the gas inlet manifold electrode 484 and the substrate support electrode 482, and forming a plasma in the processing region by applying a selected first RF power to the cleaning gas disposed in the processing region to clean a substrate processing residue (e.g., deposition residue) from the interior surfaces of the plasma processing chamber including the surfaces of the gas inlet manifold electrode 484, the substrate support electrode 482 and chamber walls 483. A second stage includes maintaining the formed plasma while a second relatively small electrode spacing across distance 488 is formed between the gas inlet manifold electrode 484 and the substrate support electrode 482 by applying a selected second RF power to the at least one of the electrodes to further clean a cleaning residue from the interior surfaces of the plasma processing chamber including the surfaces of the gas inlet manifold electrode 484, the substrate support electrode 482 and chamber walls 483.

In one example, the first relatively large electrode spacing across distance 488 is about 500 mils to about 1000 mils, for example about 600 mils for a 300 mm plasma processing chamber, and the first RF power is about 500 watts to about 750 watts (power density about 2.7-5.6 watts/cm2). The first stage may be performed for about 6 seconds to about 120 seconds, for example 30 seconds. The second relatively small electrode spacing across distance 488 is about 100 mils to about 400 mils, for example about 100 mils to about 300 mils, and the second RF power is about 500 watts to about 750 watts (power density about 2.7-5.6 watts/cm2). The second stage may be performed for about 15 seconds to about 180 seconds, for example 50 seconds.

Referring to FIGS. 4A and 4B, at block 410 and line 472, after the chamber cleaning method 400A and before time T3, an optional purge operation is initiated to purge the cleaning gases and cleaning residue from the plasma processing chamber. It has been observed that immediately after chamber cleaning, the aluminum fluoride layer, formed during the fluorinated cleaning operations at blocks 406 and 408, will vaporize and diffuse to the exposed surfaces of the gas inlet manifold from the surfaces of the substrate support if the substrate support is maintained at a temperature above 480 degrees Celsius, such as 650 degrees Celsius and the chamber pressure is low (e.g., below 8 Torr). Therefore, initiating the purge operation while the chamber pressure is at 8 Torr or greater tends to prevent the vaporized aluminum fluoride material from diffusing to the surface of the gas inlet manifold of the plasma processing chamber while the substrate support is maintained at a temperature greater than 600 degrees Celsius. Flowing the purging gas at higher pressure also helps minimize any aluminum fluoride and other unwanted residues from reaching the surface of the gas inlet manifold electrode 484 and exposed interior surfaces of other chamber components and directs the aluminum fluoride and other residues out through the chamber exhaust.

The purging may be performed by flowing a purging gas into the plasma processing chamber through the gas inlet manifold. The purging gas may include, for example, nitrogen, argon, neon, or other suitable inert gases, as well as combinations of such gases. In one exemplary implementation, the purging gas is argon. In another exemplary implementation, the purging gas is argon and nitrogen.

In some alternative implementations, the purging gas may include a silicon-containing gas, such as silane. Suitable silane gases may include silane (SiH4) and higher silanes with the empirical formula SixH(2x+2), such as disilane (Si2H6), trisilane (Si3H8), and tetrasilane (Si4H10), or other higher order silanes such as polychlorosilane. It has been observed that purging with silane is effective in scavenging the formed and deposited aluminum fluoride (AlFx) residues and free fluorine radicals that are present in the plasma processing chamber. It is contemplated that instead of silane, any precursor gas that is chemically reactive with deposition residue (e.g., fluorine) and/or deposits by CVD or PECVD can also be used to scavenge the formed and deposited aluminum fluoride (AlFx) residue.

During purging, the pressure within the plasma processing chamber is maintained at about 8 Torr to about 30 Torr, such as about 10 Torr to about 15 Torr. The temperature of the substrate support may be maintained at about 600 degree Celsius or above, for example about 650 degrees Celsius. To achieve a higher chamber pressure, the purging gas may be introduced into the plasma processing chamber for a longer period of time with a throttle valve, which is connected to exhaust line that is connected to the vacuum pump, that is adjusted to allow contaminants (e.g., vaporized deposition residue) to be pumped from the plasma processing chamber while the required chamber pressure is maintained. In various examples discussed herein, the purging time may vary between about 10 seconds to about 90 seconds, for example about 15 seconds to about 45 seconds. In one exemplary implementation, the purging time is about 20 seconds.

In one embodiment, as shown in the insert of FIG. 4B associated with line 472, the purge block 410 may optionally include a repeating pump/purge cycle to further facilitate the purging of the cleaning gases and cleaning residue within the chamber. For example, the chamber pressure of 10 Torr may quickly be pumped down or reduced to a chamber pressure less than 10 Torr, such as 9 Torr for a period of time such a 4 seconds to clear the chamber of cleaning gases and residue. The chamber is then quickly back filled with an inert purge gas to increase the chamber pressure again to about 10 Torr for a period of time, such as about 4 seconds. This pump purge operation is repeated a number of times such as between about 1 time and 10 times, such as about 3 times. Each time the pump purge operation is repeated the concentration of the residual clean gas components is reduced until the cleaning gas components and residue are pumped out of the plasma processing chamber through the vacuum pump system.

The purging gas may be introduced into the plasma processing chamber at a flow rate of about 4000 sccm to about 30000 sccm, such as about 8000 sccm to about 24000 sccm, for example about 10000 to about 20000 sccm for a 300 mm plasma processing chamber. If two purging gases are used, the first purging gas, for example argon, may be flowed at a flow rate of about 8000 sccm to about 15000 sccm, such as about 13000 sccm, and the second purging gas, for example nitrogen, may be flowed at a flow rate of about 16000 sccm to about 24000 sccm, for example about 20000 sccm. It should be noted that the processing conditions as described in this disclosure are based on a 300 mm processing chamber.

In one example, a purging gas comprising argon is introduced into the plasma processing chamber at a flow rate of about 13000 sccm and a chamber pressure of about 10 Torr. In one another example, a purging gas comprising nitrogen is introduced into the plasma processing chamber at a flow rate of about 10000 sccm and a chamber pressure of about 10 Torr. In yet another example, a first purging gas comprising argon is introduced into the plasma processing chamber at a flow rate of about 13000 sccm and a second purging gas comprising nitrogen is introduced into the plasma processing chamber at a flow rate of about 20000 sccm, with a chamber pressure of about 10 Torr.

Referring to FIG. 4A and FIG. 4D, the seasoning operations 400B of method 400 include blocks 412 and 414 to provide chamber seasoning material 490 as shown in FIG. 4D. In one example, the seasoning operations 400B provide a chamber seasoning material 490 that includes a first seasoning layer 491 at block 412 and a second seasoning layer 492 at block 414. The seasoning material 490 forms capping or sealing layers on the internal surfaces of the chamber, such as at least the chamber walls 483 and the top surface 482A and the side surface 482B of substrate support electrode 482. The seasoning material 490 covers or caps any particles remaining after the purge block 410 and prevents these particles from depositing on the substrate during the subsequent material deposition operations. The seasoning process begins at block 412 of FIG. 4A corresponding to line 473, which extends between time T3 and time T4, of FIG. 4B. At block 412, after the processing region is purged of processing gases, and while the substrate support temperature is maintained at a temperature above about 600 degrees Celsius, such as about 650 degrees Celsius, the chamber pressure is pumped down from a pressure P1 to a pressure P2, for example from about 10 Torr to about 5 Torr over a time period between time T3 and time T4. As the chamber pressure decreases and when the pressure reaches about 8 Torr, a first chamber seasoning process at block 412 is initiated to form a first seasoning layer 491 on exposed interior surfaces of the chamber components, such as the substrate support electrode 482 and/or chamber walls 483. It has been found that the adhesion of some deposited seasoning films (e.g., TEOS or other silicon containing films) at high processing pressures (e.g., >8 Torr) can be undesirable, so in some embodiments the seasoning process is not started until the chamber pressure has been dropped to a pressure below the pressure used to perform the cleaning method 400A. Because the substrate support temperature is maintained at a high temperature, such as a temperature greater than 600 degrees Celsius, and the aluminum fluoride sublimates at high temperatures, by initiating the chamber seasoning process at 8 Torr, the high chamber pressure prevents sublimation of the aluminum fluoride during at least the first part of the chamber seasoning operations 400B. In one example, the first seasoning layer is a gradient seasoning layer where the layer is deposited while the chamber pressure is reduced from about 10 Torr to about 5 Torr over a period of time between time T3 to time T4, for example a period of time from about 10 seconds to about 40 seconds and where the chamber pressure is reduced from 8 Torr to 5 Torr over a period of time from about 15 to 30 seconds, such as about 20 seconds.

The first chamber seasoning process at block 412 may be performed by introducing a first seasoning gas and a second seasoning gas into the plasma processing chamber, either sequentially or in a gas mixture, through the gas inlet manifold. In one example, the first seasoning layer 491 is a silicon oxide layer which may be deposited by reacting a silicon-containing gas with an oxygen-containing precursor gas in the plasma processing chamber. In one example, a silicon dioxide seasoning layer is formed by reacting silane gas with molecular oxygen. In another example, the silicon dioxide seasoning layer is formed by reacting silane with nitrous oxide, nitric oxide, nitrogen dioxide, carbon dioxide, or any other suitable oxygen-containing precursor gas. In another example, the first seasoning layer 491 is an amorphous silicon layer which may be deposited by reacting a hydrogen-containing gas with a silicon-containing gas in the plasma processing chamber.

The hydrogen-containing gas and the silicon-containing gas may be provided into the plasma processing chamber in a ratio of about 1:6 to about 1:20 and a chamber pressure between about 8 Torr and about 10 Torr as the chamber pressure is reduced to pressure P2, for example 5 Torr. In one example, an amorphous silicon seasoning layer is formed by reacting a hydrogen gas with silane. Silane gas may be provided at a flow rate of about 3000 sccm to about 6000 sccm, such as about 5000 sccm, and the hydrogen gas may be provided at a flow rate of about 60 sccm to about 150 sccm, such as about 100 sccm, for a 300 mm plasma processing chamber. An RF power of about 15 milliWatts/cm2 to about 250 milliWatts/cm2 may be provided to the gas inlet manifold of the plasma processing chamber. In various examples, the chamber seasoning process may be performed from about 3 seconds to about 30 seconds, for example about 20 seconds. The processing time may vary depending on a desired thickness of the first seasoning layer.

While silane is discussed herein, it is contemplated that higher silanes with the empirical formula SixH(2x+2), such as disilane (Si2H6), trisilane (Si3H8), and tetrasilane (Si4H10) may also be used.

At block 414, and corresponding line 474 between time T4 and time T5 in FIG. 4B, after the first chamber seasoning process at block 412 is complete, a second chamber seasoning process at block 414 is optionally performed to deposit a second seasoning layer 492 on the first seasoning layer 491 where the chamber pressure is maintained at pressure P2, for example from about 3 Torr to about 7 Torr, for example 5 Torr, and the substrate support temperature is maintained at a temperature above 600 degrees Celsius, for example 650 degrees Celsius. The second seasoning layer 492 provides an additional capping layer on first seasoning layer 491 to form a seal over any residual particles formed on or in the first seasoning layer 491. The second seasoning layer may be performed by introducing a third seasoning gas and a fourth seasoning gas into the plasma process chamber, either sequentially or in a gas mixture, through the gas inlet manifold. In one exemplary implementation, the second seasoning layer is an undoped silicate glass which may be deposited by reacting a silicon-containing gas with an oxygen-containing precursor gas in the plasma processing chamber. In one example, an undoped silicate glass seasoning layer is formed by reacting tetraethylorthosilane (TEOS) with ozone (O3). It is contemplated that additional silicon sources such as silane, TMCT or similar sources, and other oxygen sources such as O2, H2O, N2O and similar sources and mixtures of the same also can be employed. When TEOS is used as a silicon-containing gas, a carrier gas such as helium or nitrogen may be employed. The ratio of 03 to TEOS may range from about 2:1 to about 16:1, such as about 3:1 to about 6:1.

During deposition of the second seasoning layer, TEOS may be introduced into a 300 mm plasma processing chamber at a flow rate of between about 600 mgm to about 3500 mgm, for example about 1200 mgm to about 1600 mgm. O3 (between about 5-16 wt % oxygen) is introduced at a flow rate of between about 2500 sccm to about 16000 sccm, such as about 5500 sccm to about 12000 sccm. Helium or nitrogen may be used as a carrier gas that is introduced at a flow rate of between 2600 sccm to about 12000 sccm, such as about 4500 sccm to about 8500 sccm. In most cases, the total flow of gases into the plasma processing chamber may be varied between about 8000 sccm to about 30000 sccm, such as about 15000 sccm to about 22000 sccm. In various examples, the second chamber seasoning process may be performed between time T4 and time T4 for about 10 seconds to about 220 seconds, for example about 30 seconds. The processing time may vary depending on a desired thickness of the second seasoning layer.

Referring to block 416 of FIG. 4A and line 474 of FIG. 4B, before time T5 of FIG. 4B, the plasma processing chamber is purged with a purging gas to remove any processing residues (e.g., silane) from the plasma processing chamber and clear the processing chamber of any residual gases remaining from the seasoning processes in preparation for the next processing operation. The purging may be performed by flowing a purging gas into the plasma processing chamber through the gas inlet manifold. The purging gas may include, for example, nitrogen, argon, neon, or other suitable inert gases, as well as combinations of such gases. In one exemplary implementation, the purging gas is argon. The process condition for the purging at block 416 may be identical or similar to those discussed at purge block 410 except that the purging time at block 416 may be shorter. For instance, the purging time may vary between about 2 seconds to about 10 seconds, such as about 3 seconds to about 8 seconds. In one exemplary implementation, the purging time is about 5 seconds. Thereafter, any reaction residues and/or unwanted gases are pumped out of the plasma processing chamber through the vacuum pump system.

After completion of block 416, the method 400 may proceed to the next process operation, such as block 401 where a high temperature material deposition process is performed. The method 400 may, alternatively, start again from block 402 to block 416 and begin another round of cleaning method 400A and seasoning operations 400B. In one example, after completion of the purge process at block 416, the seasoning operations 400B may begin so as to provide another round of seasoning layer to further prevent aluminum fluoride sublimation and reduce chamber particles. It is contemplated that the method 400 described herein may also be performed periodically. For example, the method 400 may be performed after every process sequentially performed on one or more substrates or after performing a pre-defined number of substrate processing cycles (e.g., deposition processes) sequentially performed on substrates. The pre-defined number may be between 1 and 6, for example 2 to 5, such as after 3 substrates have been sequentially processed. Depending upon the chamber conditions, any of the processes as described at blocks 402 to 416 may be repeated as many times as necessary until a desired chamber condition is achieved or a standard full chamber cleaning process becomes necessary.

Referring to FIG. 4B, at time T5, once the purge operation of block 416 is complete and method 400 is complete, while the substrate support temperature is maintained above 600 degrees Celsius, for example at about 650 degrees Celsius, the pressure of the processing chamber is again ramped up, from pressure P2 to pressure P1, as shown as line 475 between time T5 and time T6, for example the pressure is increased from 5 Torr to 10 Torr. The increase of chamber pressure to 10 Torr prevents the aluminum fluoride sublimation from surface areas of the chamber or chamber components that may not have received adequate seasoning during seasoning operations 400B. Surfaces that may not have received adequate seasoning include the sides of the substrate support and surfaces underside portions of the substrate support. Sublimation of the aluminum fluoride from these surfaces can cause aluminum fluoride buildup on surfaces of the gas inlet manifold and chamber walls leading to particles and drift of process variable such as temperature.

At line 476 between time T6 and time T7 while maintaining the chamber pressure at 10 Torr and the substrate support temperature at 650 degrees Celsius, a substrate may be transferred into the processing chamber and onto the substrate support. In one example, a substrate is transferred into the processing chamber from a substrate transferring chamber where the substrate transferring chamber is also maintained at pressure of about 10 Torr, or otherwise a pressure equal to that of the pressure of the processing chamber.

At line 477, between time T7 and time T8 the chamber pressure is reduced from P1, such as about 10 Torr, to the determined substrate processing pressure PP in preparation of the subsequent material deposition material processing operation. At line 478 and time T8 the chamber pressure is at PP, the substrate support is maintained at a temperature greater than about 600 degrees Celsius, such as about 650 degrees Celsius, and a deposition process to deposit material on the substrate begins.

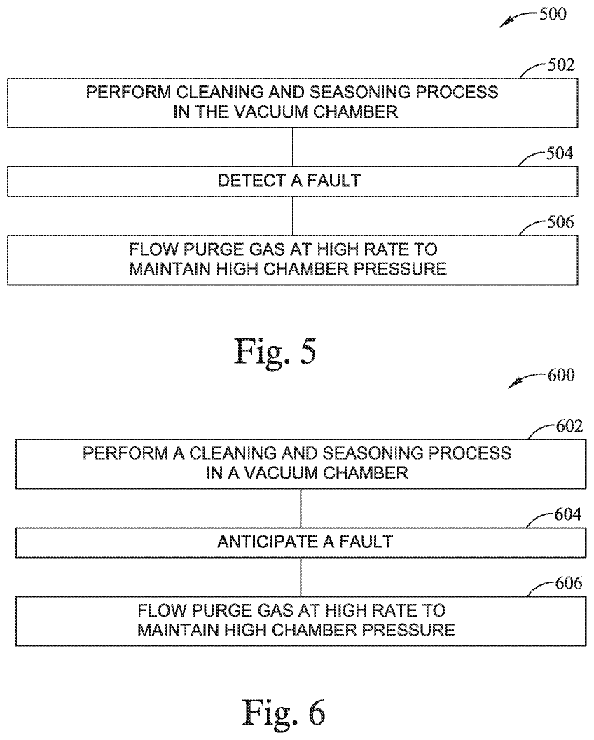

Referring again to FIG. 2, during regular chamber operation, the chamber temperature, pressure and other process parameters are monitored by sensors associated I/O devices within controller 180 to assure that any changes to the process parameters are identified and corrective actions are taken to mitigate the negative effects of any process parameter faults. Because of the risk of aluminum fluoride sublimation at high processing temperatures, the monitoring and controlling of the chamber and process parameters during different stages of a chamber's operation, such as the high temperature chamber clean process is critical. FIG. 5 depicts a method 500 for taking corrective action during the cleaning and seasoning method 400 shown in FIG. 4A. For example, referring to FIG. 5, at operation 502, during the high temperature and high pressure chamber clean, the process chamber is monitored using the controller 180 and I/O devices 187, for example, pressure sensors and temperature sensors. At operation 504, chamber faults are identified by the controller 180 whenever the temperature, pressure, gas flow rates or other process parameters fall outside a predetermined range associated with each process parameter. The process parameter settings are often referred to in the industry as equipment constants. At operation 506, if a chamber fault is detected, the controller 180 using the software applications 183 stored in memory 186 initiates a protocol to minimize any damage to the chamber hardware. In one embodiment, when a chamber fault is identified, during one or more of the high temperature processes performed within the method 400, due to the high sublimation rate of the aluminum fluoride at pressure below 10 Torr, the controller 180 initiates a corrective action to fill the chamber with a purge gas such as nitrogen, argon, neon or other inert gases, or combination of inert gases, to achieve a specified pressure, such as greater than about 10 Torr, to prevent the sublimation of the previously formed aluminum fluoride layer found on one or more of the chamber components. In one example, the chamber pressure is controlled to a pressure between about 10 Torr and about 760 Torr, such as a pressure between about 10 Torr and about 500 Torr, or even a pressure between about 15 Torr and about 100 Torr. In one embodiment, the chamber pressure is then maintained at a desired pressure (e.g., about 10 Torr) until the substrate support and chamber temperature has reach a temperature that the aluminum fluoride is not susceptible to sublimation, such as below 480 degrees Celsius. Therefore, due to the actions taken by the controller 180, due to its detection of a fault and the instructions found in the software applications 183 stored in memory 186, the chamber will be brought to a safe state where the damage to the various chamber components and contamination generated within the processing region can be reduced or prevented. In one example, the software applications 183 may include commands that when executed by the processor will cause the chamber to be physically isolated from the rest of the system (e.g., close an open slit valve), the temperature of the substrate support to be lowered to a desired temperature and the pressure in the chamber to be controlled to a desired level (e.g., about 10 Torr) by the control of the pumping system and/or the delivery of a gas into the processing region of the chamber.

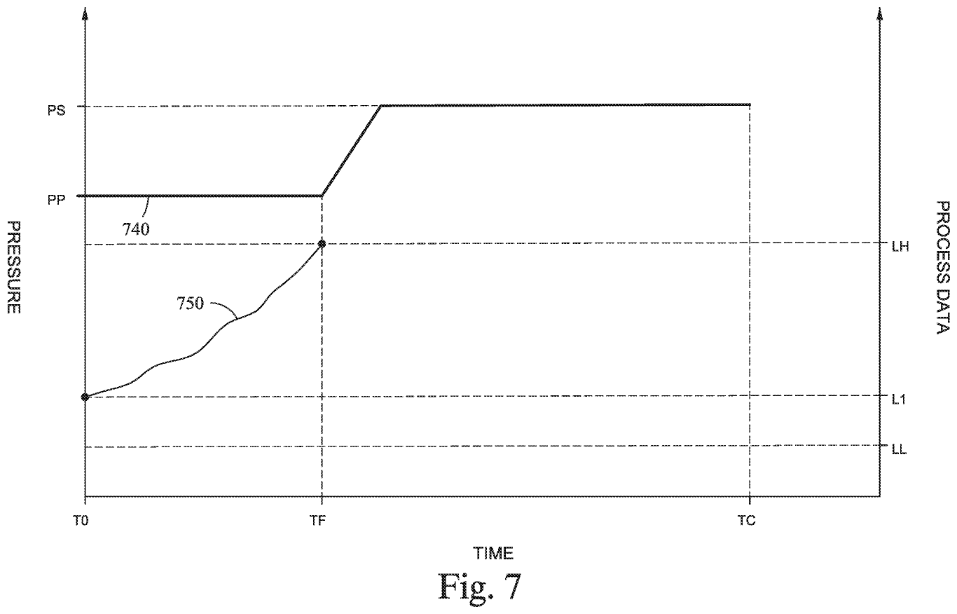

FIG. 6 shows a method 600 taking a preventative corrective action during different stages of a chamber's operation, such as during a high temperature cleaning and seasoning process when a fault is anticipated. FIG. 7 shows a chart where the processing pressure represented by line 740 is tracked against time T, and a process parameter represented by line 750, such as substrate support temperature, is tracked against time T and corrective action is taken to prevent sublimation of aluminum fluoride should it be determined that the process parameter represented by 750 will likely reach a preset upper limit value LH for the monitored process parameter. Referring to both FIG. 6 and FIG. 7, at operation 602, during the high temperature and high pressure chamber process, which in this example includes a clean process, the process parameters related to the processing system are monitored using the controller 180 and I/O devices, for example sensors, such as pressure sensors to monitor the chamber pressure and temperature sensors to monitor the substrate support and chamber temperature. In one example, the desired substrate support temperature starts at value L1 for the clean process is, for example, 650 degrees Celsius, while the chamber pressure is maintained at target chamber pressure at PP, such as 10 Torr. At operation 604 of FIG. 6, during the chamber clean and season process, the controller 180 monitors all process parameters and anticipates any chamber faults associated with the monitored process parameters. For example, process parameter represented by line 750 of FIG. 7 shows the tracking of the temperature of the substrate support as the temperature is monitored using a temperature sensor. As the temperature of the substrate support is monitored using the temperature sensors, the software application tracks the temperature over time and compares the temperature provided by signal from the temperature sensors against the predetermined equipment constants values LL and LH, where values LL and LH represent an acceptable operating temperature range of the substrate support for the processing conditions. In the current example, value LL represents the limit at the low end of the acceptable temperature range and value LH represents the limit at the high end of the temperature range. The software applications 183 compare the temperature of the substrate support against the stored data 185 within memory 186. In this example the stored data includes fault models and substrate support temperature trends over time and faults from previous processes. For example, as the substrate support temperature increases from value L1, for example 650 degrees Celsius, over a period of time, between time T0 and time TF, to value LH, at for example 652 degrees Celsius, algorithms within the software applications 183 in memory 186 track and anticipate a fault based on real-time temperature readings from the temperature sensor and comparison and analysis of stored data and limit values. As the algorithm makes a determination that a fault is imminent, such as a projection that a fault will occur at time TF of FIG. 7, based on system monitoring and stored historical data, the controller initiates corrective action to place the chamber in a safe state. In one example, the software applications 183 may cause the chamber to be physically isolated from the rest of the system (e.g., close an open slit valve), the temperature of the substrate support to be lowered to a desired temperature and the pressure in the chamber to be controlled to a desired level (e.g., about 10 Torr) by the control of the pumping system and/or the delivery of a gas into the processing region of the chamber. In one configuration, the software applications 183 cause the chamber to flow a purge gas, such as nitrogen, argon, neon or other inert gas at a high rate to control and/or maintain the chamber pressure at a safe pressure PS, (reference FIG. 6, operation 606) such as a pressure greater than 10 Torr. In one example, the safe chamber pressure is a pressure between about 8 Torr and about 760 Torr, such as a pressure between about 10 Torr and about 500 Torr, or even a pressure between about 10 Torr and about 100 Torr. In this example, the chamber pressure control will prevent the sublimation of the aluminum fluoride from occurring until the substrate support temperature can be controlled from time TC until it is brought back within an acceptable temperature range to allow the chamber process to continue. In one example, a process parameter is monitored during the processing of a substrate and the process parameter is compared with a stored value in a memory of the substrate processing chamber. A chamber fault is anticipated based on the comparison of process parameter with the stored value and the substrate processing chamber is backfilled with a gas to maintain the substrate processing chamber at a pressure above 8 Torr. In some embodiments, when a chamber fault is anticipated based on the comparison of process parameter with the stored value and the substrate processing chamber is backfilled with a gas to maintain the substrate processing chamber at a pressure above 8 Torr. In one example, the chamber pressure is maintained at a pressure between about 8 Torr and about 760 Torr, such as a pressure between about 10 Torr and about 500 Torr, or even a pressure between about 10 Torr and about 100 Torr.

In some embodiments, the analysis of trends in one or more of the processing parameters used in a processing chamber are monitored by the processor over more than a single substrate processing cycle and thus a drift in one or more of the process parameters can be detected over time and be prevented from causing a fault during the processing of a substrate and/or during a cleaning process. The processor and software application thus may perform various data analysis techniques to determine trends and/or changes in one or more of the processing variables to detect a current fault or a fault that will likely occur at some time in the future.

In addition to the method described above, benefits of the present disclosure will also include maintaining the substrate support temperature at deposition process temperatures while purging a vacuum chamber at a higher pressure and higher flow rate to prevent aluminum fluoride vaporization from reaching a gas inlet manifold and/or exposed interior surfaces of other chamber components of the vacuum chamber. Flowing of the purging gas at a higher pressure help removes aluminum fluoride and other unwanted residues from the gas inlet manifold of the process chamber. In cases where silane is used to purge the vacuum chamber, the silane gas is provided, through the gas inlet manifold, so that it will deposit a thin amorphous silicon layer on the substrate support when the temperature of the substrate support reaches 600 degree Celsius or above. Silane is also used to scavenge any free fluorine that is present in the vacuum chamber. The formed amorphous silicon layer prevents aluminum fluoride from sublimating and reaching the gas inlet manifold. It has been observed that only 0.2-0.3 μm thickness of aluminum fluoride is deposited on the gas inlet manifold after processing of 1000 substrates. As a result, the life time of the substrate support, gas inlet manifold and/or chamber components are elongated by the addition of this process. The process rate drifting or wafer temperature drifting (due to gas inlet manifold emissivity change from aluminum fluoride build up) in the vacuum chamber is avoided and the overall chamber stability is improved.

While the foregoing is directed to embodiments of the present disclosure, other and further embodiments of the disclosure may be devised without departing from the basic scope thereof.

What is claimed is:

1. A method of processing a substrate in a substrate processing chamber, comprising:
performing a first process within a processing region of the substrate processing chamber, wherein a substrate support disposed within the processing region is maintained at a first process temperature that is above 600 degrees Celsius;
performing an in-situ chamber clean process within the substrate processing chamber, wherein the in-situ chamber clean process comprises:
maintaining the substrate support temperature at a clean process temperature that is above 600 degrees Celsius;
controlling the processing region to a pressure above 8 Torr; and
performing a chamber clean process using a cleaning gas, wherein the cleaning gas reacts with a residue disposed on a surface of a chamber component disposed within the substrate processing chamber to remove the residue therefrom;
purge the substrate processing chamber while maintaining the substrate support at a purge process temperature that is above 600 degrees Celsius.

2. The method of claim 1, wherein the first process temperature, the clean process temperature, and the purge process temperature are each maintained at a temperature of 650 degrees Celsius or greater.

3. The method of claim 1, wherein the clean process temperature and the first process temperature are the same temperature.

4. The method of claim 1, wherein the processing region is controlled to a pressure of 10 Torr or greater during the in-situ chamber clean process.

5. The method of claim 1, wherein the processing region is controlled to a pressure above 8 Torr for the duration of the in-situ chamber clean process.

6. The method of claim 1, wherein the cleaning gas comprises fluorine and the substrate support comprises aluminum.

7. The method of claim 1, wherein the cleaning process further comprises forming a plasma within the processing chamber.

8. A method of controlling a substrate processing chamber, comprising:
maintaining a substrate support disposed within a processing region of a substrate processing chamber at a first process temperature that is above 600 degrees Celsius;
monitoring a process parameter of the substrate processing chamber;
comparing the process parameter with a value stored in a memory of the substrate processing chamber;
determining that a chamber fault is likely to occur in the future based on the comparison of the process parameter with the value stored in memory; and
adjusting a pressure within the substrate processing chamber to a pressure above 8 Torr after determining that the chamber fault is likely to occur and after determining that the substrate support is maintained at a temperature that is above 600 degrees.

9. The method of claim 8, wherein the substrate support comprises aluminum.

10. The method of claim 8, further comprising performing an in-situ chamber clean process within the substrate processing chamber.

11. The method of claim 10, wherein the processing region is controlled to a pressure of 10 Torr or greater during the in-situ chamber clean process.

12. The method of claim 10, wherein the processing region is controlled to a pressure above 8 Torr for the duration of the in-situ chamber clean process.

13. The method of claim 10, wherein the in-situ chamber clean process uses a cleaning gas comprising fluorine.

14. The method of claim 10, wherein the in-situ chamber clean process further comprises forming a plasma within the processing chamber.

15. A method for treating a substrate processing chamber, comprising:
performing a first process within the substrate processing chamber with a substrate support maintained at a temperature above 600 degrees Celsius;
monitoring a process parameter of the substrate processing chamber;
comparing the process parameter with a value stored in a memory of the substrate processing chamber; and
adjusting a pressure within the substrate processing chamber to a pressure above 8 Torr when a chamber fault is detected, wherein the chamber fault is detected by comparing the process parameter with the value stored in memory.

16. The method of claim 15, wherein the substrate support is maintained at a temperature of 650 degrees Celsius or greater, and wherein the substrate support comprises aluminum.

17. The method of claim 15, further comprising performing an in-situ chamber clean process within the substrate processing chamber.

18. The method of claim 17, wherein the processing region is controlled to a pressure of 10 Torr or greater during the in-situ chamber clean process.

19. The method of claim 17, wherein the processing region is controlled to a pressure above 8 Torr for the duration of the in-situ chamber clean process.

20. The method of claim 17, wherein the in-situ chamber clean process further comprises forming a plasma using a cleaning gas comprising fluorine within the processing chamber, and wherein the substrate support comprises aluminum.
